(19) United States
(12) Patent Application Publication
(10) Pub. No.: US 2007/0026626 A1
(43) Pub. Date: Feb. 1, 2007

(54) Integrated decoupling capacitor process

(75) Inventors: Robert Ditizio, Petaluma, CA (US); Steve Selbrede, Novato, CA (US)

Correspondence Address: Tue Nguyen, 2201 S. McDowell Blvd., Petaluma, CA, 94954, US

(73) Assignee: Tegal Corporation

(21) Appl. No.: 11/494,368

(22) Filed: Jul. 26, 2006

Related U.S. Application Data
(60) Provisional application No. 60/702,864, filed on Jul. 27, 2005.

(51) Int. Cl. H01L 21/20

(52) U.S. Cl. 438/396

(57) ABSTRACT

The present invention discloses a fabrication process for integrated high dielectric constant capacitors for circuit decoupling. The top electrode is protected against the re-deposition of material from the bottom electrode during the patterning process of the bottom electrode, thus provides better capacitor yield against the shortage of top and bottom electrodes. The protection can be a sidewall spacer, or an extra hard mask protecting the sidewall of the top electrode. The dielectric for the decoupling capacitors is preferably novel high dielectric constant materials such as (Ba₁₋ₓCaₓ)(Ti_{1-y}Zr_{y})O₃ (BCTZ). The used of novel BCTZ high dielectric constant materials requires compatible electrode or seed layer such as Au or NiV, plus a low power etching process to avoid material damage.

This application claims priority from U.S. provisional applications Ser. No. 60/702,864, filed Jul. 27, 2005, entitled “Integrated decoupling capacitor process”, which is incorporated herein by reference.

### FIELD OF THE INVENTION

The present invention generally relates to semiconductor integrated circuits and, more particularly, to capacitors having high dielectric constant materials.

### BACKGROUND OF THE INVENTION

High frequency integrated circuits (IC) are highly susceptible to noise problems such as switching noise propagating through power connection, causing signal delays, which degrades the performance of the circuits. As a result, large decoupling capacitors are coupled to the power supply to provide noise immunity and power surge suppression for proper circuit operation.

The decoupling capacitors are typically discrete capacitors mounted adjacent to the IC chip and connected to the power conductors. Discrete capacitors take up large space, and thus decoupling capacitors are costly in terms of real estate. Further, the interconnection to the discrete coupling capacitors might be long, and thus increasing the inductance and resistance of the decoupling capacitors, which affects the high frequency performance of the decoupling capacitors. And in addition to high capacitance, the decoupling capacitors typically have high inherent inductance and resistance, causing signal propagation degradation.

One possible solution is to include the coupling capacitors on the IC chip. However, large planar capacitors require significant surface area and thereby create difficult yield and density problems.

### SUMMARY OF THE DESCRIPTION

The present invention provides an integrated large area high dielectric constant capacitor for circuit decoupling. The decoupling capacitors are preferably processed after metallization and passivation and resulted in an IC chip with planar decoupling capacitors on the chip surface, ready to be bonded to the substrate. By protecting the sidewall of the top electrode before etching the bottom electrode, the present invention fabrication process provides better yield enhancement against possible shortage of the top and bottom electrode due to the re-deposition of bottom electrode material across the dielectric layer onto the top electrode. The protection can be a sidewall spacer, or an extra hard mask protecting the sidewall of the top electrode. The dielectric for the decoupling capacitors is preferably novel high dielectric constant materials such as (Ba₁₋ₓCaₓ)(Ti_{1-y}Zr_{y})O₃ (BCTZ). The used of novel BCTZ high dielectric constant materials requires compatible electrode or seed layer such as Au or NiV, plus a low power etching process to avoid material damage.

### BRIEF DESCRIPTION OF THE DRAWINGS

FIG. 1 shows a schematic of decoupling capacitor.

FIG. 2 shows the prior art IC chip with contacts.

FIG. 3 shows an embodiment of the present invention sidewall spacer protecting the top electrode before etching the bottom electrode.

FIG. 4 shows another embodiment of the present invention hardmask protecting the top electrode before etching the bottom electrode.

FIG. 5 shows an embodiment of the present invention IC chip with integrated decoupling capacitor, employing sidewall spacer protection.

FIG. 6 shows an embodiment of the present invention IC chip with integrated decoupling capacitor, employing hardmask protection.

FIG. 7 shows a typical process flow of the present invention for sidewall spacer protection.

FIG. 8 shows a typical process flow of the present invention for hardmask protection.

FIGS. 9-1 to 9-11 show an embodiment of the fabrication process of the present invention integrated decoupling capacitor.

FIG. 10 shows an typical etch system for the present invention.

### DETAIL DESCRIPTION OF THE INVENTION

The present invention discloses an integrated high dielectric constant decoupling capacitor. The basic high dielectric constant material for large capacitors is typically barium titanate material such as Ba₁₋ₓSrₛTiO₃ (BST) as this material possesses high dielectric constants and low loss. In the present invention, the high dielectric constant material is preferably barium titanate with partial substitution by calcium zirconate. The compound is in the form (Ba₁₋ₓCaₓ)(Ti_{1-y}Zr_{y})O₃ with Ca substitutes for Ba and Zr substitutes for Ti, typically called BCTZ.

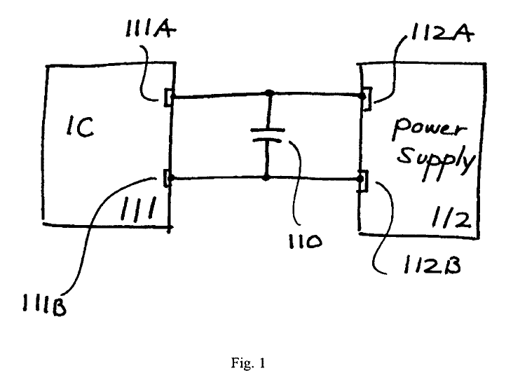

FIG. 1 shows a schematic of a decoupling capacitor 10 between an IC chip 111 and a power supply 112. The decoupling capacitor 110 is typically connected in parallel with the power supply 112 and the IC chip 111. Power supply chip is normally separated from the IC chip, and the connection between these two chips is packaged on a substrate such as a PCB board. The IC chip 111 and the supply chip 112 include contact 111A, 111B and 112A, 112B respectively, and these contacts are connected on the substrate. The packaging method can be wire bonding, TAB bonding, surface mount bonding (SMT), solder bump bonding, etc.

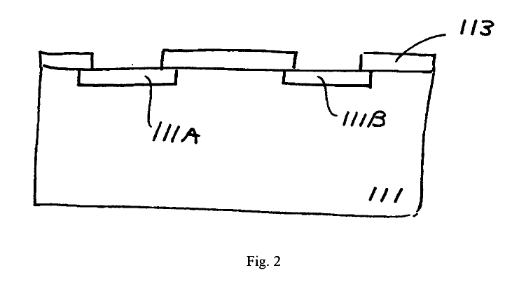

FIG. 2 shows a schematic of the IC chip 111 with the contacts 111A and 111B. The chip 111 also contains devices and interconnections, which are not shown for clarity. The chip also contains a plurality of contacts and among them, only two contacts are shown in FIG. 2. The surface of the chip is passivated with a passivation layer 113, leaving only the contacts exposed.

To achieve high cpacitance, the dielectric thickness is designed to be as thin as possible. The thin thickness of the dielectric layer creates some difficulty in etching the electrodes, since the material from the bottom electrode can re-deposited onto the top electrode, bridging the dielectric layer, and creating an electrical shortage. In an embodiment, the present invention discloses a protection coverage for the top electrode before the etching of the bottom electrode. The protection is fabricated after the formation of the top electrode.

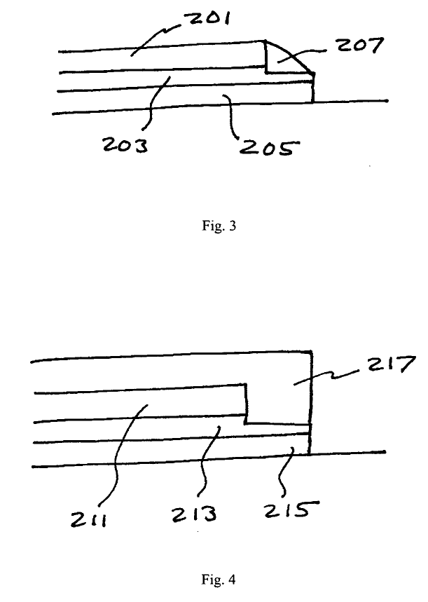

FIG. 3 shows an embodiment of the present invention fabrication process for the capacitor. The capacitor comprises a top electrode 201 and a bottom electrode 205, sandwiching an insulator (e.g. dielectric) layer 203. The electrode is a conducting material, and therefore if the capacitor is etched straight down, the conducting materials can bridge the diectric gas, creating electrical shortage. To prevent the etching of the bottom electrode from reaching the top electrode, the top exposed top electrode sidewall is covered with a sidewall spacer 207. Any material sputtered from the bottom electrode would deposit on the spacer, thus preventing possible shortage to the top electrode.

FIG. 4 shows another embodiment of the protection of the top electrode. After the top electrode 211 is etched, a portion of the dieelctric layer 213 is preferably etched to ensure the compleness of the etching of the top electrode. A hardmask 217 is then patterned with the bottom electrode size (preferably slightly larger than the top electrode). The hardmask is then etched, and through the bottom electrode 215. The presence of the hardmask 217 protect the sidewall of the the top electrode, preventing shortage.

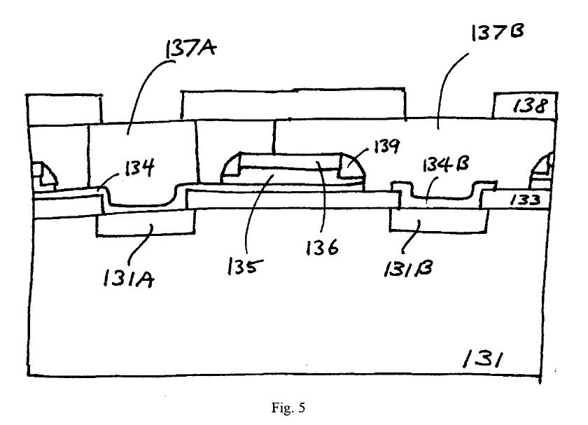

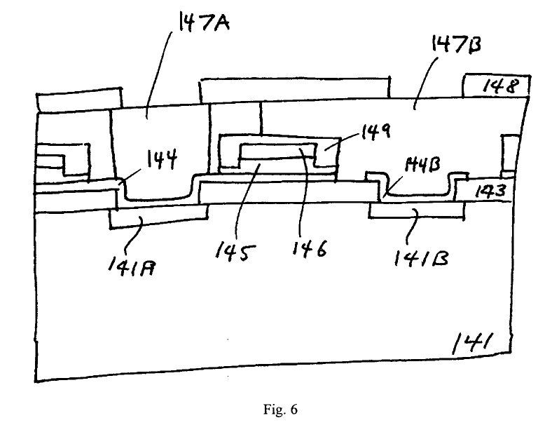

FIGS. 5 and 6 show two embodiments of the present invention fabrication process for the capacitor in an IC chip, employing the concept of FIGS. 3 and 4, respectively. The integrated decoupling capacitor is fabricated on the surface of the chip 131/141, comprising a high dielectric constant material 135/145 sandwiched between two conductor layers 134/144 and 136/146. The conductor layer 134/144 is contacting the contact 131A/141A together with a new contact 137A/147A. The conductor layer 136/146 is contacting the contact 131B/141B through the new contact 137B/147B. Between the new contact 137B/147B and the contact 131B/141B is a separate section 134B/144B of the conductor layer 134/144. This section 134B/144B is optional, meaning that it is not needed for the operation of the decoupling circuit, but would help in improving the circuit yield without putting too much burden on the fabrication process. Spacers 139/149 are used to isolate the top and bottom conductor layers 134/144 and 136/146, similar to that of FIGS. 3 and 4. The chip is also passivated with the layer 138/148, leaving the new contacts 137A/147A and 137B/147B. The final configuration of the contacts of the IC chip 131/141 does not change, and thus the integrated decoupling capacitor chip can employs the same fabrication process as the old configuration chip.

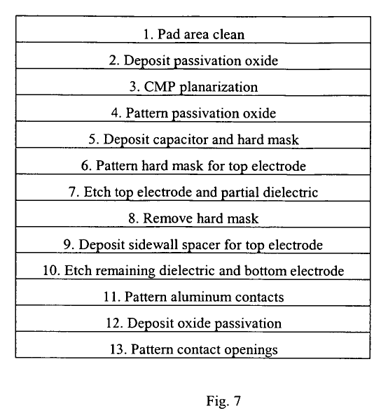

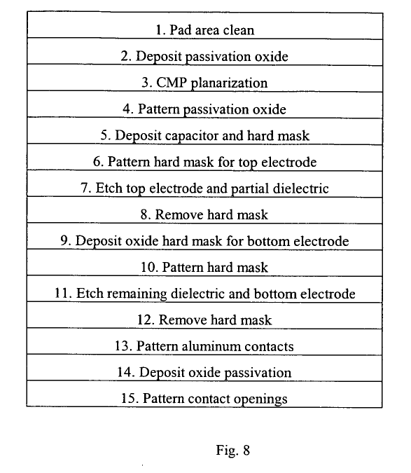

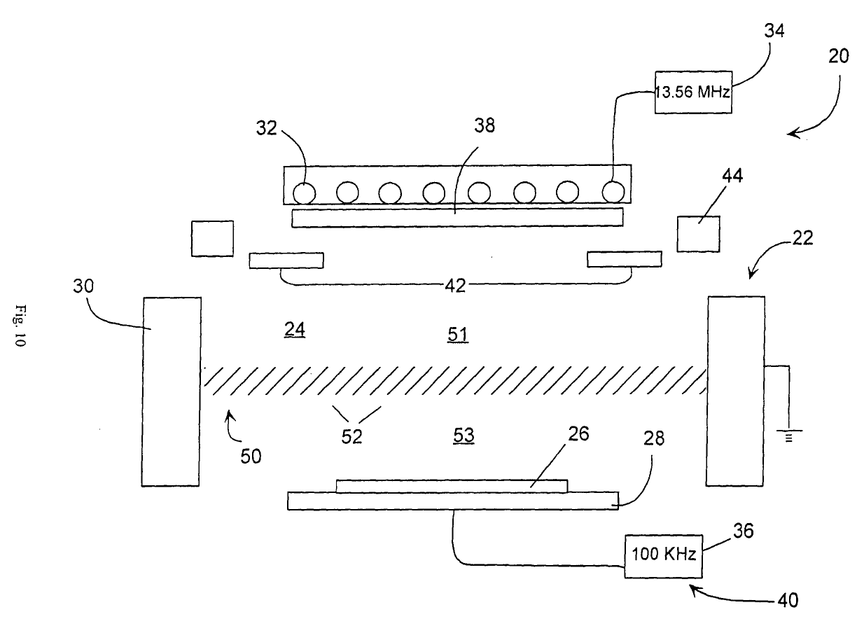

FIGS. 7 and 8 shows a typical fabrication process flow for the integrated decoupling capacitor chip, according to the concept of FIGS. 3 and 4, respectively. The fabrication is meant as an example, since there are obvious deviation and modification without departing from the scope of the invention. FIGS. 9-1 to 9-34 show the cross section of a fabrication sequence.

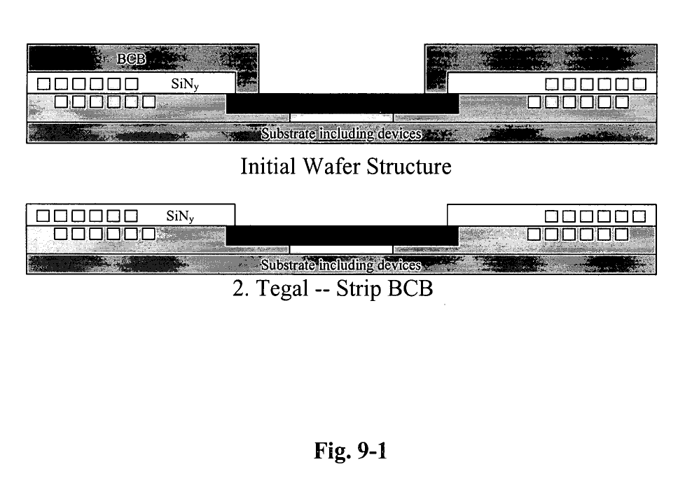

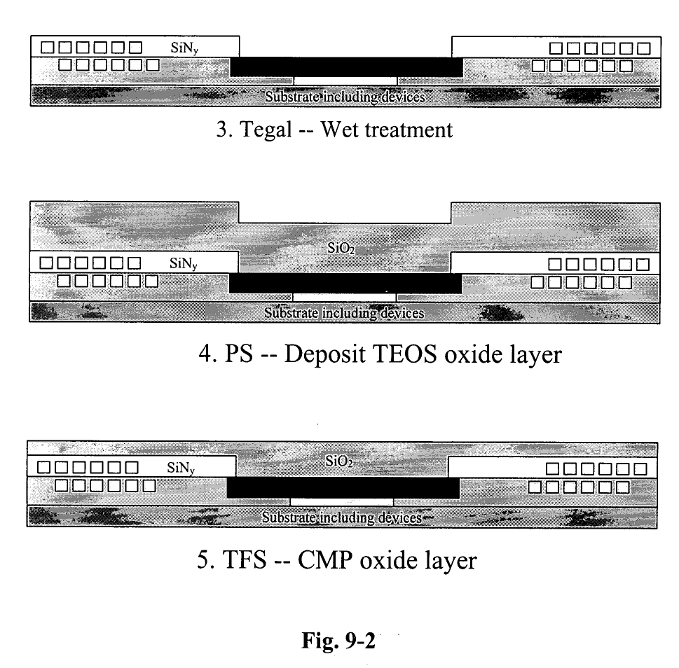

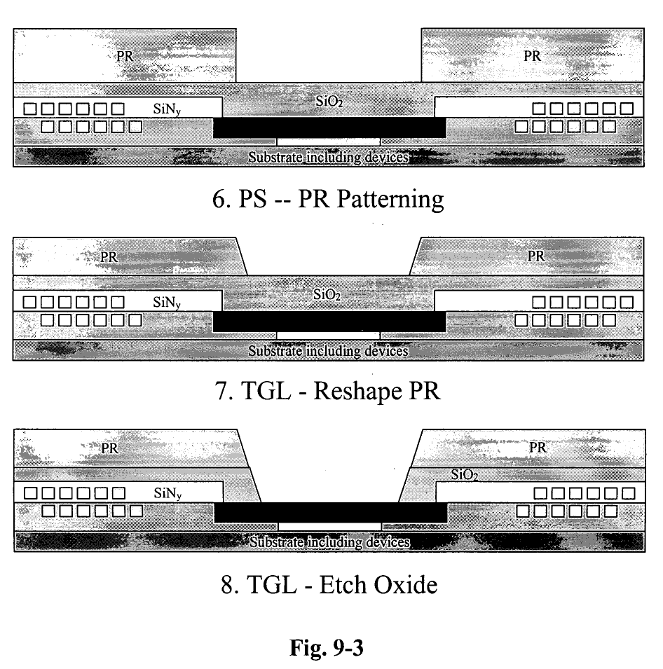

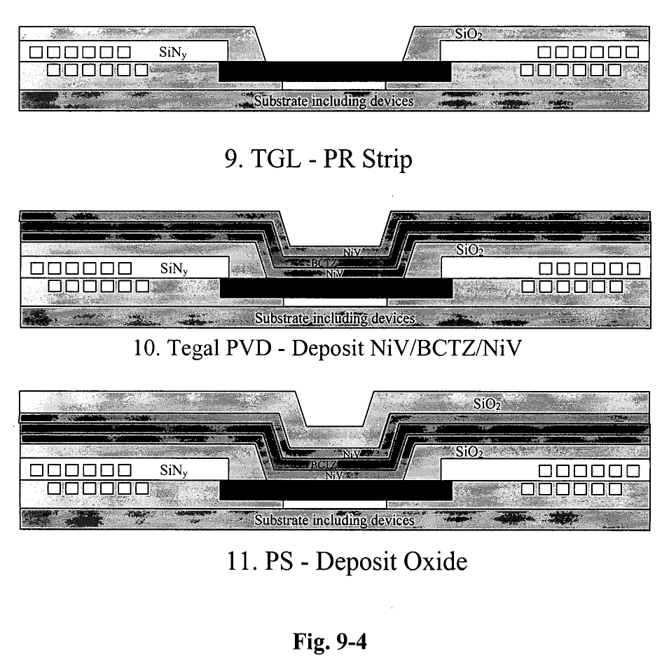

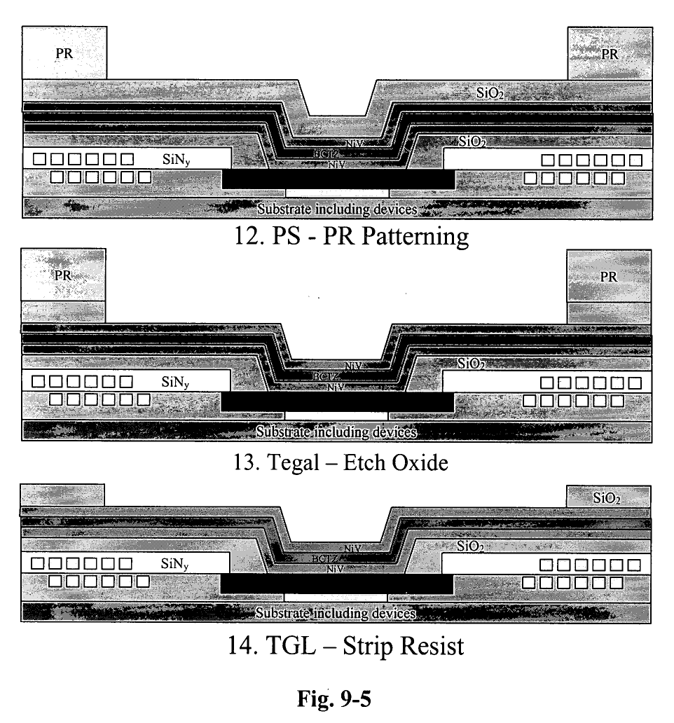

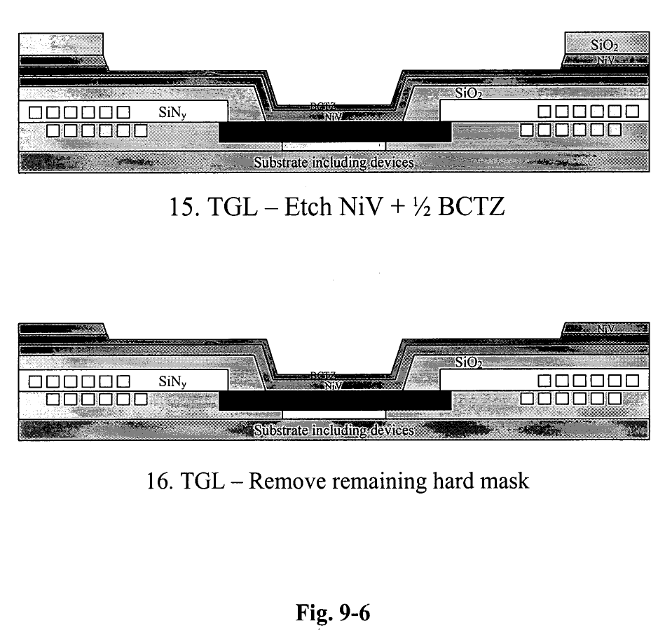

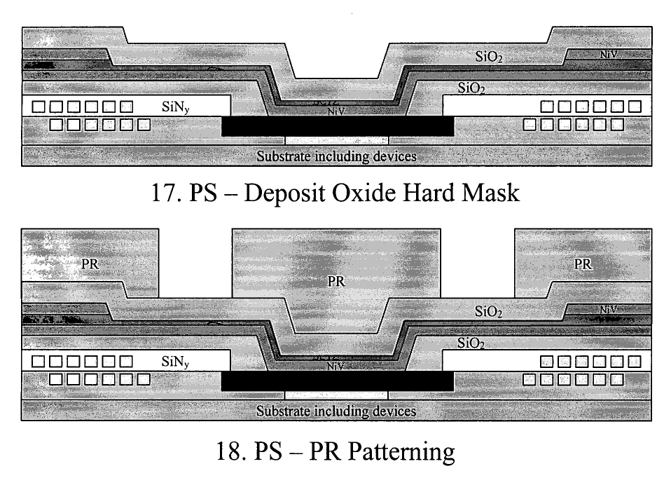

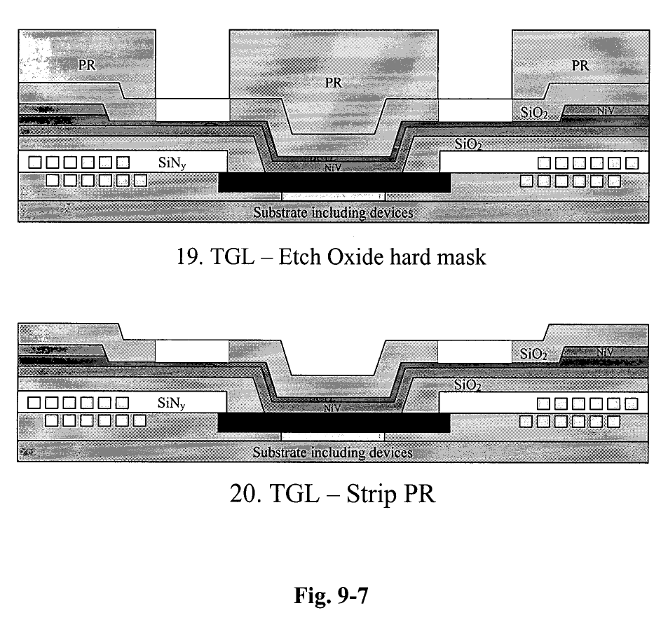

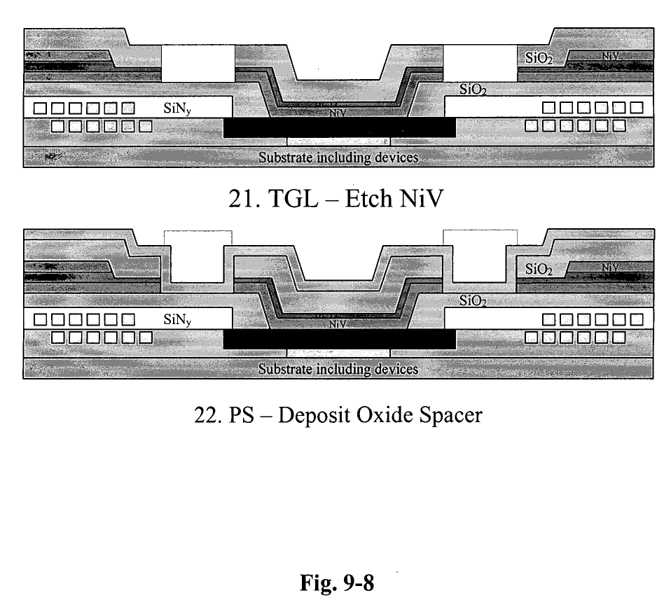

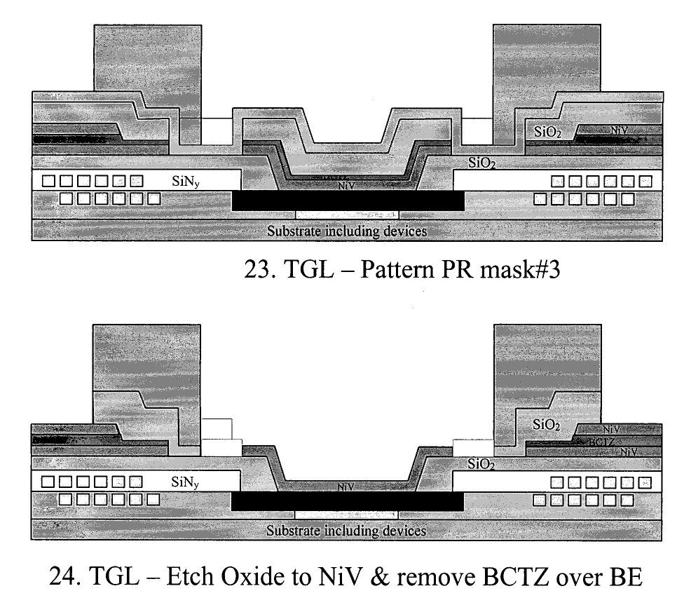

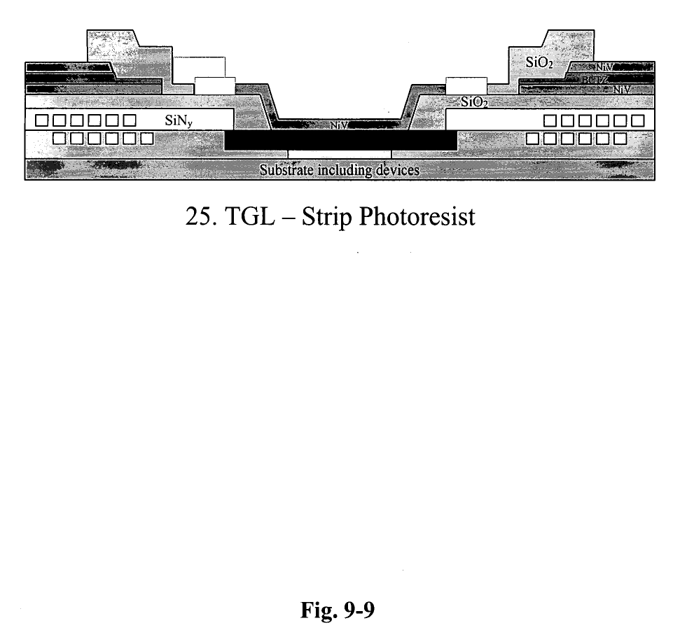

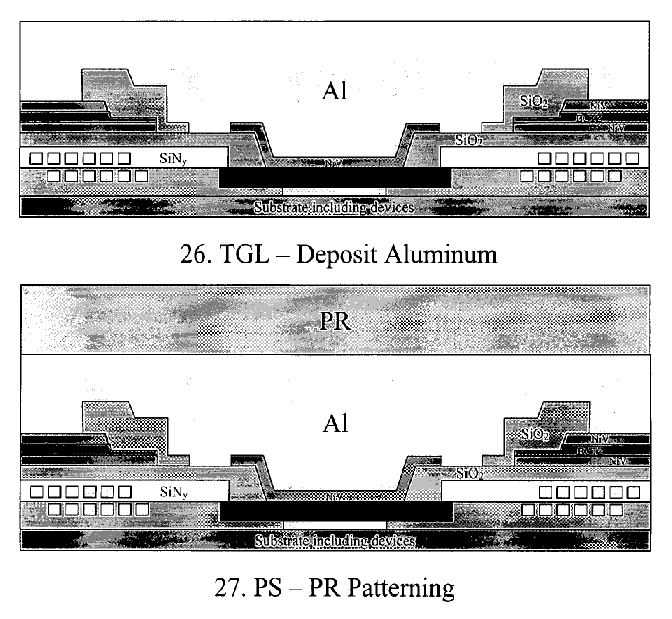

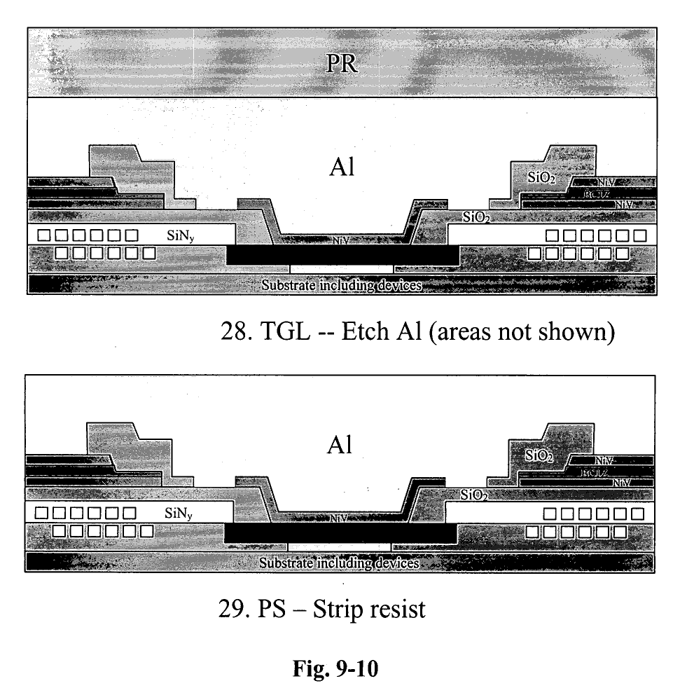

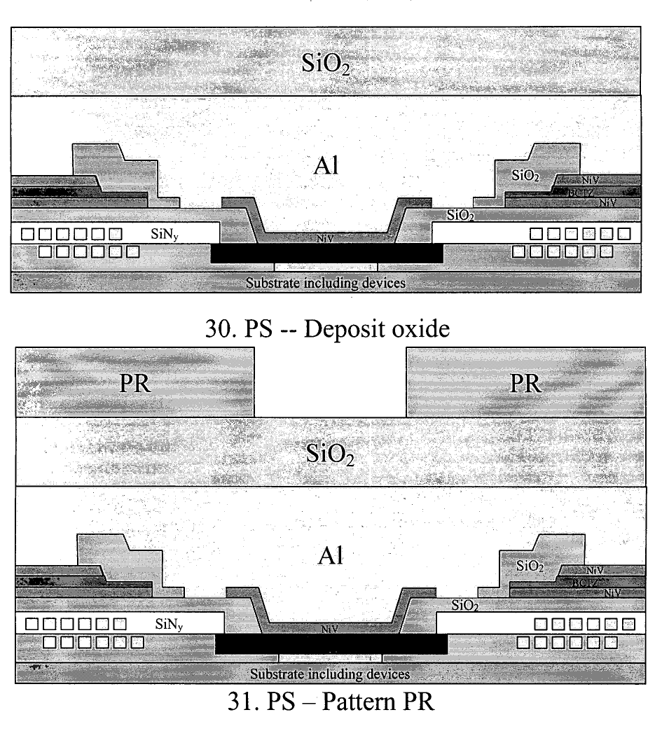

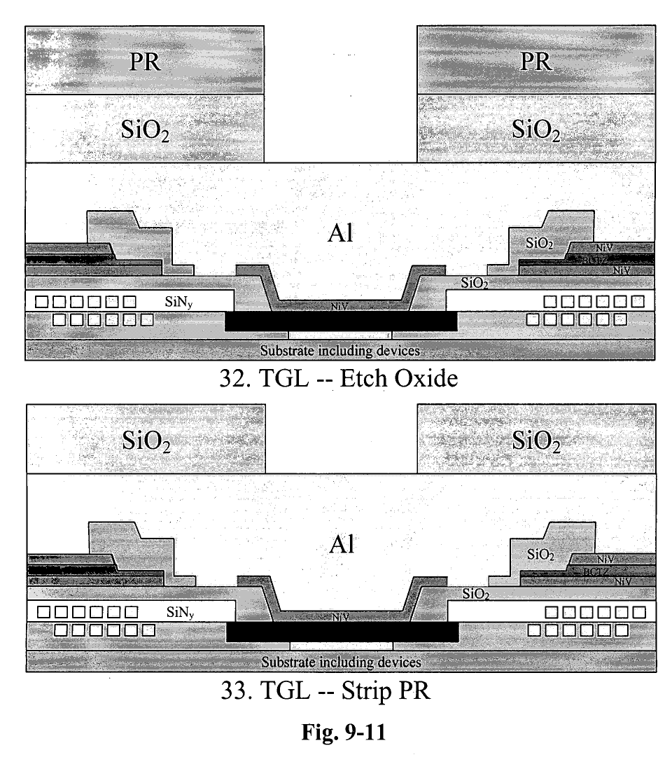

FIG. 9-1 shows the initial wafer structure, comprising a substrate including devices, and a contact pad with passivation layer of SiN_{y}. The passivation layer covers the whole surface of the chip, leaving only the contact pads exposed.

The chip surface is cleaned, typically with a HF solution before the deposition of a TEOS oxide layer. The TEOS oxide layer is preferably thick enough to fill the contact. The TEOS oxide layer is then planarized by CMP to provide a planar surface. FIG. 9-2 shows the chip surface after planarization. The planarization step helps the ease of fabrication, but is not essential to the novelty of the present invention.

With the planarization step, the contacts need to be open again. Thus a photolithography step is employed to expose the contact. The photolithography step includes a photo resist deposition, photo resist exposure to pattern the photo resist. Then the TEOS oxide planarized layer is etched to expose the contact, as shown in FIG. 9-3. The contact is large compared to the device dimension, and a sloped profile is desirable for better step coverage during subsequent steps. Thus this contact exposure step is preferably performed to achieve a sloped profile as shown in FIG. 9-3. The sloped profile can be achieved by an oven bake step of the photo resist after patterning to reshape the photo resist profile. The TEOS etching is then performed with an isotropic etching to ensure the gradual slope of the TEOS oxide layer during etch.

After the contact etch, the photo resist is removed. The decoupling capacitor is deposited, first with a bottom conductor layer, then the dielectric layer, and then the top conductor layer. The fabrication process further continued with a hard mask layer of silicon oxide, as shown in FIG. 9-4. The sloped profile of the contact openings serves to improve the conformality of the capacitor layer deposition, avoiding pin holes and thickness defects. The conductor layers serves as the electrodes for the capacitor and the bottom conductor layer also serves as a seed layer for the dielectric layer.

The chip is then subjected to another photolithography step to pattern the hard mask silicon oxide layer as shown in FIG. 9-5. The use of the hard mask is optional, dictated by the need for the capacitor etching. Novel materials such as high dielectric constant material of BCTZ require hard mask during etching instead of the conventional photo resist.

Using the hard mask, the top conductor layer and a portion of the dielectric layer is etched as shown in FIG. 9-6. The reason for the etching of the dielectric is to ensure the complete etching of the top conductor layer, achieved by the significant over-etching of the top conductor layer and onto the dielectric layer.

Another hard mask photo lithography is next, with the deposition of a hard mask oxide layer, followed by a photolithography step and the etching of the hard mask layer, and completed with the removal of the photo resist, as shown in FIG. 9-7.

The hard mask oxide is then served to etch the remaining dielectric layer and the bottom conductor layer. A thin oxide spacer layer is then deposited to cover the exposed conductor layers and the dielectric layer, as shown in FIG. 9-8. This patterning step is to separate one contact from the bottom conductor layer.

The next step is a photolithography step to expose the contact and the top conductor layer while preserving the coverage of the spacer between the top and bottom conductors, as shown in FIG. 9-9. The area above the contact pad is etched clean to the bottom conductor layer, and the top conductor layer is also etched clean. The bottom and the top conductor layers are ready to make new contact.

New aluminum contacts are formed using another photolithography step. One aluminum contact contacts the bottom conductor layer only to an old contact and one aluminum contact contacts the top conductor layer to another old contact, as shown in FIG. 9-10.

New oxide passivation layer is then deposited, and a photolithography step is performed to open the new contacts, as shown in FIG. 9-11.

The integrated decoupling capacitor process described above can use any kind of dielectric materials. To increase the capacitance, high dielectric constant material is preferable, with BCTZ material is preferred material. For BCTZ, the electrode, or seed layer, has to be compatible. Thus the present invention discloses electrode materials for BCTZ dielectric to be either Au or NiV. The fabrication process can include an optional spacer after the top electrode etch to reduce potential shorting damage between the top and the bottom electrode across from the BCTZ dielectric.

With the novel materials of BCTZ and its electrodes, the etching processes presented here are also novel. The main issues with BCTZ and electrodes etch is to minimizing damage to the materials. Since the BCTZ material is highly susceptible to damage, etching of the BCTZ material and its interface must be optimized. Thus the present invention discloses an etch process for BCTZ and its electrode by using lower power to reduce material damage. For the top electrode etch, the beginning is not critical since BCTZ is still protected, thus higher power can be used to upto 90% of the top electrode thickness. Alternatively, wet chemistry can also employed since BCTZ is found to be susceptible to high power oxygen and hydrogen species. Two step etch process for the top electrode can be used: a first step with high power to high throughput, and then a second step of low power etch or a wet etch to minimize damage to the BCTZ layer.

Furthermore, photoresist stripping can cause damage to BCTZ layer due to energetic oxygen or hydrogen. Thus low power resist stripping is desirable. Alternatively, wet stripping can be used for minimizing damage.

The method of the present invention can be performed in an etch reactor such as the etch reactor depicted in FIG. 6. It is to be understood that other reactors including but not limited to other etch reactors and other chuck configurations can be used and be within the scope and spirit of the invention.

FIG. 10 depicts a plasma reactor 20 of the present invention. The plasma reactor in this particular embodiment is an inductively coupled plasma reactor. It is to be understood that the essence of the invention can be practiced in other types of reactors such as ECR, Helicon and other ICP reactors as well as capacitively coupled reactors. Thus, the invention is advantageous for any variety of reactors which can perform a variety of operations and which can cause the deposition of materials from the surface of a wafer onto other surfaces such as a power transfer window. The reactor 20 configured in this embodiment to perform an etching process. The reactor 20 includes a housing 22 and a reactor or etched chamber 24. A wafer 26 is positioned on a chuck incorporated with a bottom electrode 28. The chamber 24 further includes a side peripheral electrode 30 which can be grounded or allowed to establish a floating potential as a result of the plasma developed in the chamber 24. The reactor 20 includes an upper electrode 32 which in this embodiment includes an inductor coil.

Preferably, the reactor 20 includes two A.C. power sources. A first power source 34 is connected to the upper electrode 32 and a second power source 36 is connected to the bottom electrode 28. Appropriate circuitry for both connections may include matching networks. Further, a controller 40 controls the sequencing of the first and second AC power source 36, 38. In this embodiment, the first power source 34 is operated in the megahertz range, and preferably operates at about 13.56 MHz although other frequencies in the MHz and GHz range can be used with the present invention. The second power source 32 preferably operates in the kHz range and is optimally operated at about 450 kHz and generally in the range that is less than about 500 kHz. However, the second power supply can also be operated into the MHz range. It is to be understood that ion energy increases toward the kHz range while ion density increases toward the MHz range. Further, the wafer electrode can have applied thereto mixed frequency power supplies such as power supplies in the kHz and MHz ranges, or in the kHz and GHz ranges. The present embodiment further includes a process gas inlet head 42 and process gas outlet port 44. While the reactor chamber of FIG. 6 depicts top pumped systems, it is to be understood other reactor systems which have process gas inlet and outlet ports in various other locations of the reactor system, including but not limited to ports associated with a bottom chuck electrode, can benefit from the present invention.

A power transfer window 38, which is generally comprised of quartz or any other material which allows the power that is transferred through the inductive coil of upper electrode 32 to be coupled to the reactor chamber 24, is positioned adjacent to the inductive upper electrode 32.

The invention further includes a shield 50 which in the present embodiment includes a plurality of louvers or slats 52 which are positioned at a skewed angle with respect to the wafer 26 and the bottom electrode 28. This shield can prevent the deposition of materials onto the power transfer window 38 so that power coupling with the electrode 32 through the window is not reduced or eliminated. The deposition of materials can occur from a number of mechanisms such as sputtering, condensation, and the like. Although reference is made below to sputter shields, such shields can prevent deposition by any of said number of mechanisms.

In this embodiment of FIG. 6, the shield 50 interrupts a line-of-sight sputter path between a material sputtered from the wafer 26, and the window 38 and the induction coil 32. A particular sputter shield 50 includes louvers 52 which overlap in order to block material sputtered from the wafer 26. In a preferred embodiment, the sputter shield 50 can be comprised of quartz, ceramic, or other insulating materials which are appropriate to the reactor chamber. Conductors can also be used for the shield. The sputter shield 50 can in fact be analogized to a set of Venetian blinds which have been partially opened. The sputter shield 50 prevents materials and in particular metals from metals films on a semiconductor wafer 26 from being sputtered and deposited on the window 38. Such metals could reduce or eliminate the coupling of power between the inductive coil of upper electrode 32 and the reactor chamber 24. Alternatively, the deposition shield can be placed adjacent to the window 38 or incorporated into the window 38.

For BCTZ and NiV etch, the high frequency power is in the order of 100 W, ranging from 40 to 400 W, and the low frequency power is in the order of 20W, ranging from 5 to 100 W. To further prevent reactor coating, the chamber sidewall is maintained at around 80° C., ranging between 40 to 120° C. The substrate temperature is about room temperature, ranging from 10 to 50° C. Other parameters are typical of etch process, such as milliTorr process condition (2-30 mTorr), Argon process gas (100-500 sccm), He backside (1-10 T). This etch process can etch successfully with minimum damage to both BCTZ and its electrode of NiV. Further fine-tuning is also possible for etch selectivity between BCTZ and NiV.

What is claimed is:

1. A method for producing an integrated capacitor, the integrated capacitor comprising a bottom electrode, a high-k insulator and a top electrode, the method comprising a protection of the sidewalls of the top electrode before etching the bottom electrode.

2. The method of claim 1 wherein the protection of the top electrode sidewall is performed by sidewall spacers.

3. The method of claim 1 wherein the protection of the top electrode sidewalls is performed by patterning a protetion coverage of the top electrode.

4. A method for producing an integrated capacitor comprising the steps of:
a) depositing a bottom electrode conductor layer;
b) depositing a high-k insulator layer;
c) depositing a top electrode conductor layer;
d) etching the top electrode layer and a portion of the high-k layer, stopping before reaching the bottom electrode;
e) providing a hardmask layer that covers the sidewalls of the etched top electrode and the etched portion of the high-k insulator layer;
f) etching of the remaining high-k dielectric layer and the bottom electrode conductor layer to form the integrated capacitor.

5. The method of claim 4 further comprising a step of depositing a hardmask layer on top of the top electrode layer.

6. The method of claim 4 wherein the integrated capacitor is a decoupling capacitor.

7. The method of claim 4 where the high-k dielectric layer is BCTZ, PZT, BST, SBT, or a multilayer of these films.

8. The method of claim 4 where the top electrode or the bottom electrode is platinum, gold, nickel, nickel-vanadium alloy, ruthenium, iridium, iridium oxide, or a multilayer of these materials.

9. The method of claim 4 where the etching of the electrodes or the insulator layer is performed by plasma etching, ion milling, or wet chemical etching.

10. The method of claim 4 where the plasma etching is performed at very low power to reduce charge damage to the high-k film.

11. The method of claim 4 where the low power plasma etching is performed near endpoint and during overetching.

12. A method for producing an integrated capacitor comprising the steps of:
a) depositing a bottom electrode conductor layer;
b) depositing a high-k insulator layer;
c) depositing a top electrode conductor layer;
d) etching the top electrode layer and a portion of the high-k layer, stopping before reaching the bottom electrode;
e) depositing a spacer insulator layer;
f) etching the spacer insulator layer to create a sidewall spacer covering the sidewalls of the etched top electrode and the etched portion of the high-k insulator layer;
g) etching of the remaining high-k insulator layer and the bottom electrode conductor layer to form the integrated capacitor.

13. The method of claim 12 further comprising a step of exposing a metal pad before depositing the bottom electrode layer, wherein the bottom electrode layer contacts the metal pad.

14. The method of claim 12 further comprising a step of depositing a hardmask layer on top of the top electrode layer.

15. The method of claim 12 wherein the integrated capacitor is a decoupling capacitor.

16. The method of claim 12 where the high-k dielectric layer is BCTZ, PZT, BST, SBT, or a multilayer of these films.

17. The method of claim 12 where the top electrode or the bottom electrode is platinum, gold, nickel, nickel-vanadium alloy, ruthenium, iridium, iridium oxide, or a multilayer of these materials.

18. The method of claim 1,2, and 3, where the etching of the electrodes or the insulator layer is performed by plasma etching, ion milling, or wet chemical etching.

19. The method of claim 12 where the plasma etching is performed at very low power to reduce charge damage to the high-k film.

20. The method of claim 12 where the low power plasma etching is performed near endpoint and during overetching.
